(19) United States
(12) Patent Application Publication
(10) Pub. No.: US 2026/0134892 A1
(43) Pub. Date: May 14, 2026

(54) SEMICONDUCTOR DEVICE AND MANUFACTURING METHOD THEREOF

(71) Applicant: CXMT Corporation, Hefei City (CN)

(72) Inventors: Chao LIN, Hefei City (CN); Ruisong LIU, Hefei City (CN); Lihua XU, Hefei City (CN)

(73) Assignee: CXMT Corporation, Hefei City (CN)

(21) Appl. No.: 19/218,171

(22) Filed: May 23, 2025

Related U.S. Application Data
(63) Continuation of application No. PCT/CN2025/080721, filed on Mar. 5, 2025.

(30) Foreign Application Priority Data
Nov. 13, 2024 (CN) 202411622327.2

(51) Int. Cl. G11C 5/06; H10B 12/00

(52) U.S. Cl. CPC G11C 5/063; H10B 12/02; H10B 12/482; H10B 12/488

(57) ABSTRACT

A semiconductor device includes: a substrate; common electrode structures stacked on the substrate in a first direction; stacked array structures including first electrode structures, where the first electrode structures are stacked on the substrate in the first direction and are electrically connected to the common electrode structures disposed at the same layers with the first electrode structures; first lead-out structures stacked in the first direction and connected to the common electrode structures disposed at the same layers with the first lead-out structures, where the first lead-out structures include first lead-out wires and first pseudowires that are disposed opposite to each other, and the first lead-out wires and the first pseudowires in the different first lead-out structures are alternately disposed in the first direction.

### CROSS-REFERENCE TO RELATED APPLICATIONS

This is a continuation application of International Patent Application No. PCT/CN2025/080721 filed on Mar. 5, 2025, which claims priority to Chinese Patent Application No. 202411622327.2 filed on Nov. 13, 2024. The disclosures of the above-referenced applications are hereby incorporated by reference in their entirety.

### BACKGROUND

The development of a dynamic memory (DRAM) seeks performance indicators such as a high speed, a high integrated density, and low power consumption. With miniaturization of the structure size of a semiconductor device, a technical barrier encountered by an existing structure becomes increasingly obvious. Therefore, on the basis of the existing structure, more novel structures are developed, which is an advantageous means to break the existing technical barrier.

The appearance of a three-dimensional dynamic random access memory (3D DRAM), in particular, a 3D DRAM including a multilayer horizontal cell (Multilayer Horizontal Cell, MHC), which usually includes multiple transistors stacked on a substrate, meets the foregoing requirement.

In a current 3D DRAM structure, reducing a parasitic capacitance between word lines or bit line lead-out wires is an urgent problem to be solved.

### SUMMARY

Embodiments of the present disclosure relate to the field of semiconductor technologies, and in particular, to a semiconductor device and a manufacturing method thereof.

According to a first aspect of embodiments of the present disclosure, a semiconductor device is provided, including:
a substrate; common electrode structures, where the common electrode structures are stacked on the substrate in a first direction, and the first direction intersects the substrate;
stacked array structures, where the stacked array structures include first electrode structures, and the first electrode structures are stacked on the substrate in the first direction and are electrically connected to the common electrode structures disposed at the same layers with the first electrode structures;
first lead-out structures, where the first lead-out structures are stacked in the first direction and are connected to the common electrode structures disposed at the same layers with the first lead-out structures, the first lead-out structures include first lead-out wires and first pseudowires that are disposed opposite to each other, and the first lead-out wires and the first pseudowires in the different first lead-out structures are alternately disposed in the first direction; and
second lead-out structures, where the second lead-out structures include second contact pads and second contact plugs, the second contact pads are disposed at the same layers with the corresponding first lead-out wires and are electrically connected to the corresponding common electrode structures through the corresponding first lead-out wires, the second contact plugs are disposed on the second contact pads, and the second contact plugs are staggered from each other in the first direction.

In some embodiments, the first lead-out structures extend in a third direction, the second lead-out structures are staggered in the third direction, and the third direction is parallel to the substrate.

In some embodiments, the first lead-out structures extend in a third direction, the third direction is parallel to the substrate, the second lead-out structures are disposed in a second direction, projections of the second lead-out structures on the substrate in the first direction partially overlap, and the second direction is parallel to the substrate and intersects the third direction.

In some embodiments, the first lead-out wires connected to the second lead-out structures whose projections on the substrate in the first direction partially overlap are spaced apart by at least one layer.

In some embodiments, the first electrode structures include bit line structures or word line structures.

In some embodiments, both ends of the first lead-out structures are connected to the common electrode structures.

In some embodiments, the second contact pads and the first lead-out wires are unibody.

In some embodiments, the second contact pads and the second contact plugs are unibody.

In some embodiments, each of the first pseudowires includes laminated polysilicon and silicon nitride.

According to a second aspect of embodiments of the present disclosure, a manufacturing method for a semiconductor device is provided, including the steps as follows:

A substrate is provided, where a stacked structure is formed on the substrate.

Common electrode structures are formed in the stacked structure.

Stacked array structures are formed in the stacked structure, where the stacked array structures include first electrode structures.

First lead-out structures are formed in the stacked structure, where the first lead-out structures include first lead-out wires and first pseudowires that are disposed opposite to each other, the first lead-out wires and the first pseudowires in the different first lead-out structures are alternately disposed in the first direction, and the first direction intersects the substrate.

Second lead-out structures are formed in the stacked structure, where the second lead-out structures include second contact pads and second contact plugs.

The common electrode structures are electrically connected to the first electrode structures formed at the same layers with the common electrode structures, the second lead-out structures are electrically connected to the common electrode structures through the first lead-out wires, the second contact plugs are formed on the second contact pads, and the second contact plugs are staggered from each other in the first direction.

In some embodiments, the first lead-out wires, the second contact pads, and the second contact plugs are formed in the same step.

In some embodiments, the step of forming the first lead-out structures includes the steps as follows: Filling layers are first formed, where the filling layers pad positions of the first lead-out structures;
trench structures corresponding to the second lead-out structures are formed, and the corresponding filling layers are exposed;
the exposed filling layers are removed; and
the first lead-out wires, the second contact pads, and the second contact plugs are formed, where the remaining filling layers form the first pseudowires.

In some embodiments, the filling layers are formed by depositing polysilicon and silicon nitride in a lamination manner.

In some embodiments, the forming the stacked structure includes the step as follows: A silicon layer and a silicon-germanium layer are alternately formed.

The first lead-out wires and the first pseudowires are alternately arranged, so that a first lead-out wire interval between layers can be increased, thereby reducing a parasitic capacitance.

### BRIEF DESCRIPTION OF DRAWINGS

FIG. 1 is a schematic diagram of a semiconductor device according to an example embodiment;

FIG. 2 is a schematic diagram of a semiconductor device according to an example embodiment;

FIG. 3A is a first schematic diagram of D1-D3 sections of a semiconductor device along positions of first lead-out wires in a manufacturing process according to an example embodiment;

FIG. 3B is a first schematic diagram of D1-D2 sections of a semiconductor device along a position of a second lead-out structure in a manufacturing process according to an example embodiment;

FIG. 4A is a second schematic diagram of D1-D3 sections of a semiconductor device along positions of first lead-out wires in a manufacturing process according to an example embodiment;

FIG. 4B is a second schematic diagram of D1-D2 sections of a semiconductor device along a position of a second lead-out structure in a manufacturing process according to an example embodiment;

FIG. 5A is a third schematic diagram of D1-D3 sections of a semiconductor device along positions of first lead-out wires in a manufacturing process according to an example embodiment;

FIG. 5B is a third schematic diagram of D1-D2 sections of a semiconductor device along a position of a second lead-out structure in a manufacturing process according to an example embodiment;

FIG. 6A is a schematic diagram of a D1-D3 section of a semiconductor device along positions between first lead-out wires and first pseudowires in a manufacturing process according to an example embodiment.

FIG. 6B is a fourth schematic diagram of D1-D2 sections of a semiconductor device along a position of a second lead-out structure in a manufacturing process according to an example embodiment;

FIG. 7 is a fifth schematic diagram of D1-D2 sections of a semiconductor device along a position of a second lead-out structure in a manufacturing process according to an example embodiment;

FIG. 8 is a sixth schematic diagram of D1-D2 sections of a semiconductor device along a position of a second lead-out structure in a manufacturing process according to an example embodiment;

FIG. 9 is a seventh schematic diagram of D1-D2 sections of a semiconductor device along a position of a second lead-out structure in a manufacturing process according to an example embodiment;

FIG. 10 is an eighth schematic diagram of D1-D2 sections of a semiconductor device along a position of a second lead-out structure in a manufacturing process according to an example embodiment;

FIG. 11 is a nineth schematic diagram of D1-D2 sections of a semiconductor device along a position of a second lead-out structure in a manufacturing process according to an example embodiment;

FIG. 12 is a tenth schematic diagram of D1-D2 sections of a semiconductor device along a position of a second lead-out structure in a manufacturing process according to an example embodiment;

FIG. 13A is a fourth schematic diagram of D1-D3 sections of a semiconductor device along positions of first lead-out wires in a manufacturing process according to an example embodiment;

FIG. 13B is an eleventh schematic diagram of D1-D2 sections of a semiconductor device along a position of a second lead-out structure in a manufacturing process according to an example embodiment;

FIG. 14 is a twelfth schematic diagram of D1-D2 sections of a semiconductor device along a position of a second lead-out structure in a manufacturing process according to an example embodiment; and

FIG. 15 is a thirteenth schematic diagram of D1-D2 sections of a semiconductor device along a position of a second lead-out structure in a manufacturing process according to an example embodiment.

### DETAILED DESCRIPTION

The technical solutions of the present disclosure are further described below in detail with reference to the accompanying drawings and the embodiments. Although example implementations of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not drawn to exact scale, and are merely intended to conveniently and clearly assist in describing the embodiments of the present disclosure.

It may be understood that meanings of “on”, “over”, and “above” in the present disclosure should be understood in the broadest sense, so that “on” means that it is “on” something with no intermediate feature or layer (that is, directly on something), and further includes the meaning that it is “on” something with an intermediate feature or layer.

In the embodiments of the present disclosure, the terms “first”, “second”, “third”, and the like are intended to distinguish between similar objects but do not necessarily describe a specific order or sequence.

In the embodiments of the present disclosure, the term “layer” refers to a material part including a region having a thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at the top surface and the bottom surface of the continuous structure. The layer may extend horizontally, vertically, and/or along an inclined surface. The layer may include multiple sublayers.

It should be noted that the technical solutions described in the embodiments of the present disclosure may be randomly combined when there is no conflict.

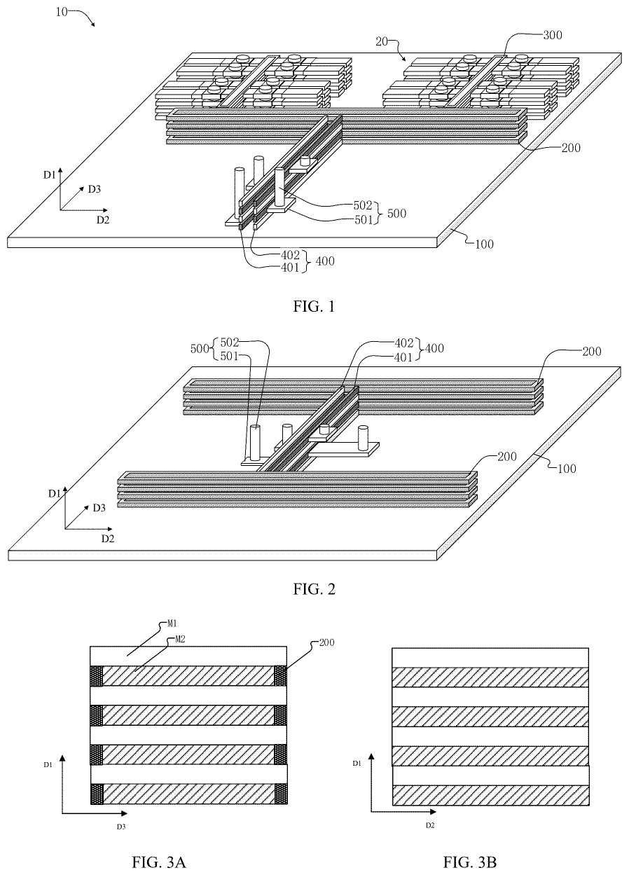

According to a first aspect of embodiments of the present disclosure, as shown in FIG. 1 to FIG. 2,
a semiconductor device is provided, including: a substrate 100; common electrode structures 200, where the common electrode structures are stacked on the substrate in a first direction D1, and the first direction intersects the substrate;
stacked array structures 20, where the stacked array structures include first electrode structures 300, and the first electrode structures are stacked on the substrate in the first direction and are electrically connected to the common electrode structures disposed at the same layers with the first electrode structures;
first lead-out structures 400, where the first lead-out structures are stacked in the first direction and are connected to the common electrode structures disposed at the same layers with the first lead-out structures, the first lead-out structures include first lead-out wires 401 and first pseudowires 402 that are disposed opposite to each other, and the first lead-out wires and the first pseudowires in the different first lead-out structures are alternately disposed in the first direction; and
second lead-out structures 500, where the second lead-out structures include second contact pads 501 and second contact plugs 502, the second contact pads are disposed at the same layers with the corresponding first lead-out wires and are electrically connected to the corresponding common electrode structures through the corresponding first lead-out wires, the second contact plugs are disposed on the second contact pads, and the second contact plugs are staggered from each other in the first direction.

In some embodiments, the first lead-out structures extend in a third direction D3, the second lead-out structures are staggered in the third direction, and the third direction is parallel to the substrate. Optionally, the second lead-out structures are distributed on two sides of the first lead-out structures in the third direction.

In some embodiments, the second lead-out structures are disposed in a second direction D2, projections of the second lead-out structures on the substrate in the first direction partially overlap, and the second direction is parallel to the substrate and intersects the third direction. Optionally, in the second lead-out structures disposed in the second direction, a projection that is of a second lead-out structure close to the first lead-out structure and that is on the substrate in the first direction falls within a projection that is of a second lead-out structure far from the first lead-out structure and that is on the substrate in the first direction. Optionally, the first lead-out structure connected to the second lead-out structure close to the first lead-out structure is located at an upper layer than the first lead-out structure connected to the second lead-out structure far from the first lead-out structure, and the second contact pad of the second lead-out structure far from the first lead-out structure passes through a lower layer to be connected to the corresponding first lead-out structure.

In some embodiments, the first lead-out wires connected to the second lead-out structures whose projections on the substrate in the first direction partially overlap are spaced apart by at least one layer. Optionally, the second lead-out structures whose projections on the substrate in the first direction partially overlap are connected to the corresponding first lead-out wires by spacing apart by multiple layers, e.g., three layers or five layers.

In some embodiments, the second lead-out structures distributed in the third direction are disposed on both sides of the first lead-out structures, and include the second lead-out structures disposed in the second direction.

In some embodiments, the first lead-out wires and the first pseudowires in the different first lead-out structures are alternately disposed in the first direction. To be specific, as shown in FIG. 1, in the first direction, a position for disposing a first lead-out wire at the first layer corresponds to a position for disposing a first pseudowire at the second layer, the position for disposing the first pseudowire at the second layer corresponds to a position for disposing a first lead-out wire at the third layer, and the position for disposing the first lead-out wire at the third layer corresponds to a position for disposing a first pseudowire at the fourth layer, and so on. The first pseudowires only fill positions, and have no function on work of the semiconductor device. Optionally, each of the first pseudowires includes laminated polysilicon and silicon nitride.

In some embodiments, as shown in FIG. 2, both ends of the first lead-out structures are connected to the common electrode structures, and each of the common electrode structures may be connected to multiple stacked array structures.

In some embodiments, the second contact pads and the first lead-out wires are unibody. Optionally, the second contact pads and the second contact plugs are unibody. Optionally, the second contact pads, the second contact plugs, and the first lead-out wires are unibody.

In some embodiments, each of the first electrode structures is a bit line structure or each of the first electrode structures is a word line structure.

In some embodiments, each of the stacked array structures includes multiple memory cells, and each of the memory cells includes a transistor and a storage node. Optionally, the storage node is selected from one or more of a storage capacitor, a phase change memory, a magnetoresistive memory, a ferroelectric memory, or the like. The stacked array structure includes multiple layers, multiple memory cells disposed at intervals are disposed at each of the layers, and memory cells at different layers are correspondingly disposed. The transistor includes a first source/drain, a second source/drain, and a gate, the first source/drain is connected to a bit line structure, and the second source/drain is connected to the storage node. Optionally, when the first electrode structure is a bit line structure, first source/drains of memory cells at the same layer in the stacked array structure are connected to the same bit line structure, and gates of memory cells corresponding to different layers are connected to the same word line structure or constitute a word line structure. Optionally, when the first electrode structure is a word line structure, first source/drains of memory cells corresponding to different layers in the stacked array structure are connected to the same bit line structure or constitute the same bit line structure, and gates of memory cells at the same layer are connected to the same word line structure or constitute the same word line structure.

In some embodiments, the common electrode structures are connected to multiple stacked array structures. Optionally, the stacked array structures are disposed at intervals along an extension direction of the common electrode structures. Optionally, multiple stacked array structures are disposed on both sides of the common electrode structures.

In some embodiments, the storage node is a storage capacitor. Optionally, a bottom electrode of the storage capacitor is disposed separately and is connected to the second source/drain of the transistor, storage capacitors in the same stacked array structure share a top electrode, and a dielectric material is disposed between the bottom electrode and the top electrode. The dielectric material of the storage capacitor may be selected from at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminium oxide, lead scandium tantalum oxide, and lead zinc niobate; or include, e.g., at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminium oxide, lead scandium tantalum oxide, and lead zinc niobate.

According to a second aspect of embodiments of the present disclosure, a manufacturing method for a semiconductor device is provided. As shown in FIG. 2, FIG. 3A, and FIG. 3B, the method includes the steps as follows: A substrate is provided, where a stacked structure is formed on the substrate; and common electrode structures 200 are formed in the stacked structure.

Optionally, the stacked structure is formed on the substrate, the stacked structure is constituted by alternating material layer M1 and material layer M2, and the material layer M1 and the material layer M2 respectively represent two different materials selected. The stacked structure may be selected from alternately deposited silicon nitride and silicon oxide, or formed by single-crystal silicon and single-crystal silicon-germanium manufactured through epitaxial growth, or formed by alternately manufactured two different thin film materials with a high etching selectivity ratio. Optionally, the stacked structure is constituted by two types of alternating materials, and is replaced, through an etching process and a deposition process, with the stacked structure constituted by the material layer M1 and the material layer M2.

Optionally, the etching process for manufacturing the stacked structure includes anisotropic etching or isotropic etching, such as dry etching or wet etching.

Optionally, the deposition process for manufacturing the stacked structure includes a physical vapor deposition (PVD) method, an atomic layer deposition (ALD) method, a pulse laser deposition (PLD) method, chemical vapor deposition (CVD), vacuum evaporation, furnace tube deposition, epitaxial growth (EPI), and the like.

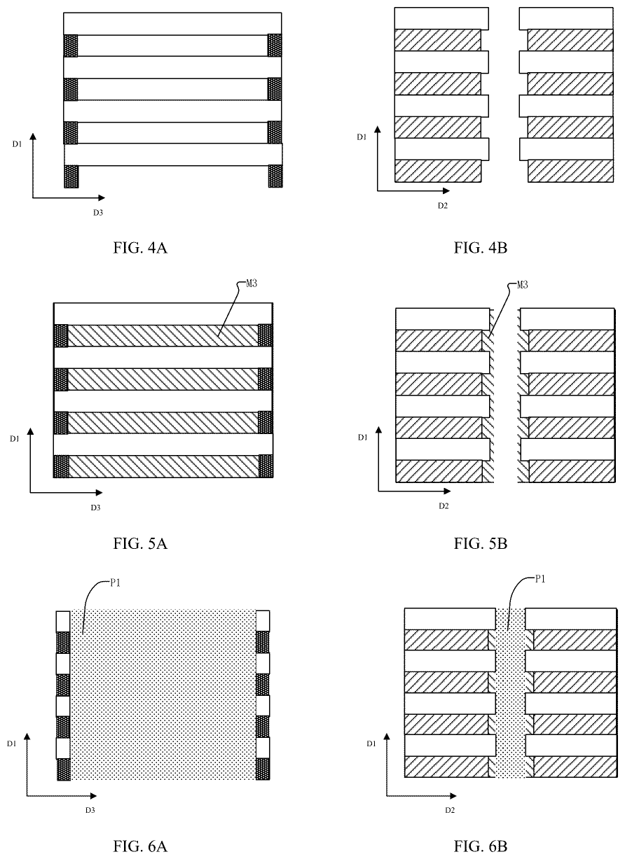

Further, as shown in FIG. 4A and FIG. 4B, a first lead-out trench is formed in a corresponding position of a first lead-out structure in the stacked structure, and the material layer M2 is laterally etched along the first lead-out trench to form a first lead-out groove, and both ends of the first lead-out groove expose the common electrode structure.

In some embodiments, a method for forming the first lead-out trench may be forming the first lead-out trench through a patterning process. Specifically, the patterning process includes the following: A photoresist is formed on the substrate, the photoresist is exposed and developed to form a photoresist with a preset pattern, and the stacked structure is etched through the patterned photoresist to form the first lead-out trench. Optionally, the etching process includes anisotropic etching or isotropic etching, such as dry etching or wet etching.

In some embodiments, the patterning process further includes the following: A hard mask is formed on the substrate, a photoresist is formed on the hard mask and the photoresist is exposed and developed to form a preset pattern, the hard mask is etched through the patterned photoresist to transfer the preset pattern to the hard mask, the photoresist is peeled, and the stacked structure is etched through the patterned hard mask to form the first lead-out trench.

In some embodiments, with development of a semiconductor manufacturing process, a degree of integration is increased, and a size is miniaturized. A preset width that requires an active region and an isolation trench cannot be formed through one patterning process cannot, and needs to be formed through multiple patterning processes, e.g., two exposing and etching processes (LELE), or self-aligned double patterning (SADP) processes, or self-aligned quadruple patterning (SAQP) processes.

In some embodiments, a method for laterally etching the material layer M2 may be a liquid-phase etching process. Optionally, the rate of etching the material layer M2 by an etching solution of the liquid-phase etching process is greater than the rate of etching the material layer M1 by the etching solution.

Further, as shown in FIG. 5A and FIG. 5B, a material layer M3 is formed in the first lead-out trench, and the material layer M3 fills the first lead-out groove and covers a sidewall of the first lead-out trench.

In some embodiments, the material of the material layer M3 may include silicon oxide, silicon nitride, silicon oxynitride, silicon carbonitride, or metal oxides such as tantalum oxide, hafnium oxide, aluminium oxide, or polysilicon, and a composition thereof. Preferably, the material of the material layer M3 includes polysilicon.

In some embodiments, a method for forming the material layer M3 is selected from processes such as a physical vapor deposition (PVD) method, an atomic layer deposition (ALD) method, a pulsed laser deposition (PLD) method, chemical vapor deposition (CVD), vacuum evaporation, and furnace tube deposition.

Further, as shown in FIG. 6A and FIG. 6B, the material layer M3 on the sidewall of the first lead-out trench is removed, the material layer M3 remaining in the first lead-out groove forms a filling layer, and a first lead-out insulating layer P1 is filled in the first lead-out trench.

In some embodiments, a process for removing the material layer M3 on the sidewall of the first lead-out trench is an anisotropic etching process including a dry etching process, a plasma etching process, and the like.

In some embodiments, the material of the first lead-out insulating layer P1 is selected from silicon oxide, silicon nitride, silicon oxynitride, silicon carbonitride, or metal oxides such as tantalum oxide, hafnium oxide, or aluminium oxide, and a composition thereof. Preferably, the first lead-out insulating layer P1 is laminated silicon oxide and silicon nitride. Optionally, a method for forming the first lead-out insulating layer P1 is selected from a physical vapor deposition (PVD) method, an atomic layer deposition (ALD) method, a pulse laser deposition (PLD) method, chemical vapor deposition (CVD), vacuum evaporation, furnace tube deposition, rapid thermal oxidation, and the like. Preferably, the method for depositing the first lead-out insulating layer P1 is the chemical vapor deposition (CVD).

In some embodiments, the method for forming the first lead-out insulating layer P1 further includes the following: The first lead-out insulating layer P1 is beyond the first lead-out trench when being formed, and the first lead-out insulating layer P1 beyond the upper surface of the stacked structure is removed, so that the upper surface of the first lead-out insulating layer P1 is flush with the first lead-out trench. A method for removing a gate insulating layer material on the surface of the substrate is selected from an etching process and chemical mechanical polishing (CMP).

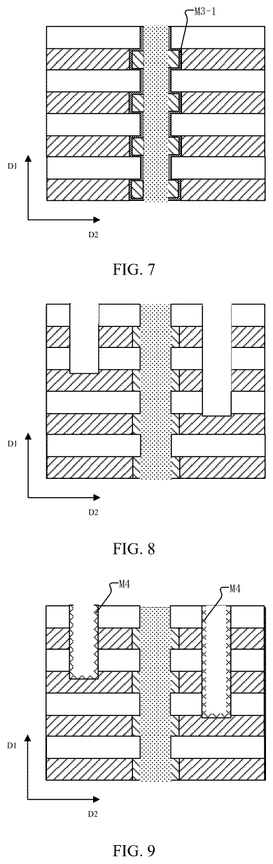

In some embodiments, as shown in FIG. 7, before the material layer M3 is formed, a barrier layer M3-1 is first formed in the first lead-out trench, and the barrier layer M3-1 covers the surface of the first lead-out groove and the sidewall of the first lead-out trench. The material layer M3 is formed in the first lead-out trench in which the barrier layer M3-1 is formed, and the material layer M3 fills the first lead-out groove in which the barrier layer M3-1 is formed and covers the sidewall of the first lead-out trench in which the barrier layer M3-1 is formed. The material layer M3 on the sidewall of the first lead-out trench is removed, and the material layer M3 remaining in the first lead-out groove and the barrier layer M3-1 in contact with the material layer M3 jointly form the filling layer. The first lead-out insulating layer P1 is filled in the first lead-out trench.

In some embodiments, the material of the material layer M3-1 may include silicon oxide, silicon nitride, silicon oxynitride, silicon carbonitride, or metal oxides such as tantalum oxide, hafnium oxide, or aluminium oxide, and a composition thereof. Preferably, the material of the material layer M3-1 is silicon nitride.

In some embodiments, a method for forming the material layer M3-1 is selected from processes such as a physical vapor deposition (PVD) method, an atomic layer deposition (ALD) method, a pulsed laser deposition (PLD) method, chemical vapor deposition (CVD), vacuum evaporation, and furnace tube deposition. Preferably, the method for forming the material layer M3-1 is the atomic layer deposition (ALD) method.

In some embodiments, when the material layer M3 on the sidewall of the first lead-out trench is removed, the barrier layer M3-1 on the sidewall of the first lead-out trench is removed together, and the material layer M3 and the barrier layer M3-1 that are remaining in the first lead-out groove jointly form the filling layer.

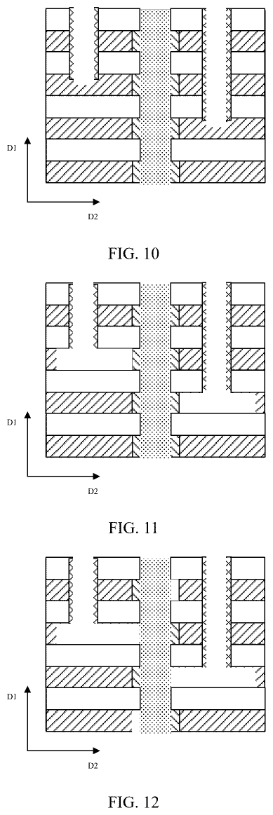

Further, as shown in FIG. 8 to FIG. 11, a contact hole with a corresponding depth is formed in a corresponding position in the stacked structure through a patterning process. Optionally, a contact hole is formed on one or both sides of the first lead-out trench. A material layer M4 is deposited in the contact hole, and the material layer M4 at the bottom of the contact hole is removed through an anisotropic etching process to expose a material layer M3 at a corresponding layer. A part of the exposed material layer M3 is removed through an isotropic etching process to form a second contact pad groove and expose a corresponding filling layer.

In some embodiments, a method for forming the contact hole includes anisotropic etching or isotropic etching, such as dry etching or wet etching.

In some embodiments, the material of the material layer M4 is selected from silicon oxide, silicon nitride, silicon oxynitride, silicon carbonitride, or metal oxides such as tantalum oxide, hafnium oxide, or aluminium oxide, and a composition thereof. Preferably, the material of the material layer M4 is selected from laminated silicon oxide and silicon nitride. Optionally, a method for forming the material layer M4 is selected from a physical vapor deposition (PVD) method, an atomic layer deposition (ALD) method, a pulse laser deposition (PLD) method, chemical vapor deposition (CVD), vacuum evaporation, furnace tube deposition, rapid thermal oxidation, and the like. Preferably, the method for forming the material layer M4 is the atomic layer deposition (ALD) method.

In some embodiments, the method for forming the material layer M4 further includes the following: When the material layer M4 is formed, the material layer M4 is also formed on the upper surface of the stacked structure, and the material layer M4 on the upper surface of the stacked structure is removed, so that the material layer M4 is formed only in the contact hole. A method for removing the material layer M4 on the upper surface of the stacked structure is selected from an etching process and chemical mechanical polishing (CMP).

In some embodiments, the anisotropic etching process for removing the material layer M4 at the bottom of the contact hole includes a dry etching process, a plasma etching process, and the like.

In some embodiments, an isotropic etching process including wet etching is employed in etching and removing a part of the exposed material layer M3 to form the second contact pad groove.

Further, as shown in FIG. 12, a corresponding filling layer is etched and removed through the contact hole and the second contact pad groove to form a first lead-out wire groove and expose a corresponding common electrode structure.

In some embodiments, an isotropic etching process including wet etching is employed in removing a part of the filling layer.

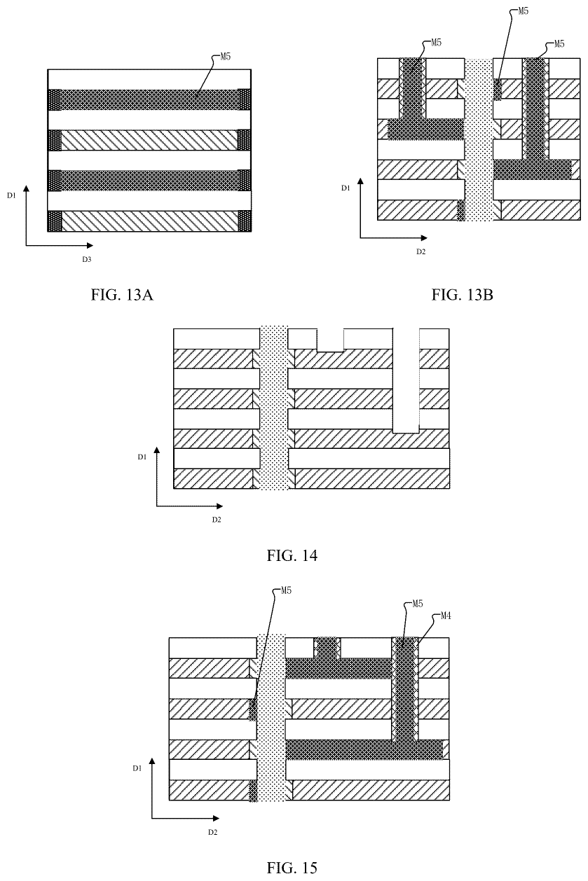

Further, as shown in FIG. 13A and FIG. 13B, a material layer M5 is formed in the contact hole, the second contact pad groove, and the first lead-out wire groove to synchronously form a first lead-out wire and an integral structure of a second contact pad and a second contact plug in corresponding positions. The first lead-out wire is electrically connected to a corresponding common electrode structure. A filling layer reserved in a position corresponding to the first lead-out wire forms a first pseudowire.

In some embodiments, the material of the material layer M5 is selected from a metal, a metal nitride, a metal oxide, a metal silicide, conductive carbon, doped or undoped polysilicon, doped or undoped single-crystal silicon, and a combination thereof, e.g., copper (Cu), aluminium (Al), tungsten (W), titanium (Ti), titanium nitride (TiN), titanium aluminium nitride (TiAlN), titanium carbonitride (TiCN), tantalum (Ta), tantalum nitride (TaN), tantalum aluminium nitride (TaAlN), tantalum carbonitride (TaCN), ruthenium (Ru), platinum (Pt), or a combination thereof. Preferably, the material layer M5 is laminated titanium nitride (TiN) and tungsten (W). A method for forming the material layer M5 is selected from a physical vapor deposition (PVD) method, an atomic layer deposition (ALD) method, a pulse laser deposition (PLD) method, chemical vapor deposition (CVD), vacuum evaporation, furnace tube deposition, and the like. Preferably, the method for forming the material layer M5 is the atomic layer deposition (ALD) method.

In some embodiments, the method for forming the material layer M5 further includes the following: When the material layer M5 is formed, the material layer M5 is also formed on the upper surface of the stacked structure, and the material layer M5 is removed from the upper surface of the stacked structure, so that the material layer M5 is formed only in the contact hole, the second contact pad groove, and the first lead-out wire groove. A method for removing the material layer M5 on the upper surface of the stacked structure is selected from an etching process and chemical mechanical polishing (CMP).

In some embodiments, when the filling layer is jointly formed by the material layer M3 and the barrier layer M3-1, as shown in FIG. 7, after the second contact pad groove exposing the filling layer is formed, the barrier layer M3-1 in the filling layer is first etched and removed through the contact hole and the second contact pad groove, then the material layer M3 in the filling layer is removed, and the corresponding common electrode structure is exposed.

In some embodiments, when the filling layer is jointly formed by the material layer M3 and the barrier layer M3-1 that are remaining in the first lead-out groove, all of the filling layer may be removed in two steps, including the following: The barrier layer M3-1 is first removed through a first isotropic etching process, and then the material layer M3 is removed through a second isotropic etching process.

In some embodiments, after the contact hole, the second contact pad groove, and the first lead-out wire groove are formed, the first lead-out wire, the second contact pad, and the second contact plug may be formed step by step. Optionally, the first lead-out wire is first formed, then the second contact pad is formed, and the second contact plug is finally formed. Optionally, an integral structure of the first lead-out wire and the second contact pad are formed in the same step, and then the second contact plug is formed. Optionally, the first lead-out wire is first formed, and then an integral structure of the second contact pad and the second contact plug is formed in the same step.

In some embodiments, when the first lead-out wire, the second contact pad, and the second contact plug are formed step by step, steps of separately forming the first lead-out wire may be as follows: a first lead-out wire material layer is first formed and fills the first lead-out wire groove through the contact hole and the second contact pad groove, and then an excess first lead-out wire material layer is removed through wet etching, where the first lead-out wire material layer remaining in the first lead-out wire groove forms the first lead-out wire; steps of separately forming the second contact pad may be as follows: a second contact pad material layer is first formed and fills the second contact pad groove through the contact hole, and then an excess second contact pad material layer is removed through wet etching, where the second contact pad material layer remaining in the second contact pad groove forms the second contact pad; and steps of separately forming the second contact plug may be as follows: a second contact plug material layer is first formed and fills the contact hole, and then an excess second contact plug material layer is removed through an etching process or chemical mechanical polishing (CMP), where the second contact plug material layer remaining in the contact hole forms the second contact plug. Similarly, an integral structure of the first lead-out wire and the second contact pad are formed in the same step, and then the second contact plug is formed; or the first lead-out wire is first formed, and then an integral structure of the second contact pad and the second contact plug is formed in the same step, which is similar to the foregoing formation method.

In some embodiments, the materials of the first lead-out wire material layer, the second contact pad material layer, and the second contact plug material layer may be the same or different, and each are separately selected from a metal, a metal nitride, a metal oxide, a metal silicide, conductive carbon, doped or undoped polysilicon, doped or undoped single-crystal silicon, and a combination thereof, e.g., copper (Cu), aluminium (Al), tungsten (W), titanium (Ti), titanium nitride (TiN), titanium aluminium nitride (TiAlN), titanium carbonitride (TiCN), tantalum (Ta), tantalum nitride (TaN), tantalum aluminium nitride (TaAlN), tantalum carbonitride (TaCN), ruthenium (Ru), platinum (Pt), or a combination thereof. Methods for forming the first lead-out wire material layer, the second contact pad material layer, and the second contact plug material layer may be the same or different, and each are separately from a physical vapor deposition (PVD) method, an atomic layer deposition (ALD) method, a pulse laser deposition (PLD) method, chemical vapor deposition (CVD), vacuum evaporation, furnace tube deposition, and the like. Preferably, the method for forming the first lead-line material layer, the second contact pad material layer, or the second contact plug material layer is the atomic deposition (ALD) method.

In some embodiments, when multiple second lead-out structures are disposed on one side of the first lead-out structure in a second direction, as shown in FIG. 14 and FIG. 15, a contact hole with a corresponding depth is formed in a corresponding position of the stacked structure through a patterning process, a material layer M4 is deposited in the contact hole, and the material layer M4 at the bottom of the contact hole is removed through an anisotropic etching process to expose a material layer M3 at a corresponding layer. A part of the exposed material layer M3 is removed through an isotropic etching process to form a second contact pad groove and expose a corresponding filling layer. A corresponding filling layer is etched and removed through the contact hole and the second contact pad groove to form a first lead-out wire groove and expose a corresponding common electrode structure. A material layer M5 is formed in the contact hole, the second contact pad groove, and the first lead-out wire groove to synchronously form a first lead-out wire and an integral structure of a second contact pad and a second contact plug in corresponding positions. The first lead-out wire is electrically connected to a corresponding common electrode structure. In second lead-out structures disposed in the second direction on the same side of the first lead-out structure, a second contact pad of a second lead-out structure far from the first lead-out structure is at a lower layer of a second contact pad close to the first lead-out structure, and there is an interval of at least one material layer M3, thereby forming a first lead-out wire and a first pseudowire that are alternately disposed in the first direction. Optionally, there may be an interval of three material layers M3 or five material layers M3.

In some embodiments, a stacked array structure is formed in the stacked structure. The stacked array structure may be manufactured before the first lead-out structure, or may be manufactured after manufacturing of the first lead-out structure is completed. The stacked array structure may be manufactured before the second lead-out structure, or may be manufactured after manufacturing of the second lead-out structure is completed. The stacked array structure is formed with multiple memory cells, and each of the memory cells is formed with a transistor and a storage node. Optionally, the storage node is selected from one or more of a storage capacitor, a phase change memory, a magnetoresistive memory, a ferroelectric memory, or the like. Multiple memory cells disposed at intervals are formed at each layer in the stacked array structure, and memory cells at different layers are correspondingly disposed. The transistor is formed with a first source/drain, a second source/drain, and a gate, the first source/drain is connected to a bit line structure, and the second source/drain is connected to the storage node. Optionally, when the first electrode structure is a bit line structure, first source/drains of memory cells at the same layer in the stacked array structure are connected to the same bit line structure, and gates of memory cells corresponding to different layers are connected to the same word line structure or constitute a word line structure. Optionally, when the first electrode structure is a word line structure, first source/drains of memory cells corresponding to different layers in the stacked array structure are connected to the same bit line structure or constitute the same bit line structure, and gates of memory cells at the same layer are connected to the same word line structure or constitute the same word line structure.

In some embodiments, an active region material of the transistor is selected from one or more or more of single-crystal silicon, single-crystal silicon-germanium, polysilicon, or an oxide semiconductor material, or is doped with other elements. The oxide semiconductor material may include indium gallium zinc oxide (InxGayZnzO, IGZO), indium gallium silicon oxide (InxGaySizO, IGSO), indium tin zinc oxide (InxSnyZnzO, ITZO), indium gallium tin oxide (InxGaySnzO, IGTO), indium zinc oxide (InxZnyO, IZO), zinc oxide (ZnxO, ZnO), zinc tin oxide (ZnxSnyO, ZTO), zinc oxynitride (ZnxOyN, ZnON), zirconium zinc tin oxide (ZrxZnySnzO, ZZTO), tin oxide (SnxO, SnO), hafnium indium zinc oxide (HfxInyZnzO, HIZO), gallium zinc tin oxide (GaxZnySnzO, GZTO), aluminium zinc tin oxide (AlxZnySnzO, AZTO), yttrium gallium tin oxide (YbxGayZnzO, YGZO), indium gallium oxide (InxGayO, IGO), or a combination thereof.

In some embodiments, a gate material is selected from a metal, a metal nitride, a metal oxide, a metal silicide, conductive carbon, doped or undoped polysilicon, doped or undoped single-crystal silicon, and a combination thereof, e.g., copper (Cu), aluminium (Al), tungsten (W), titanium (Ti), titanium nitride (TiN), titanium aluminium nitride (TiAlN), titanium carbonitride (TiCN), tantalum (Ta), tantalum nitride (TaN), tantalum aluminium nitride (TaAlN), tantalum carbonitride (TaCN), ruthenium (Ru), platinum (Pt), or a combination thereof. A method for forming the gate material is selected from a physical vapor deposition (PVD) method, an atomic layer deposition (ALD) method, a pulsed laser deposition (PLD) method, chemical vapor deposition (CVD), vacuum evaporation, furnace tube deposition, and the like. Preferably, the method for forming the gate material is the atomic layer deposition (ALD) method.

In some embodiments, a gate insulating layer is coated on the gate surface, and a gate insulating layer material is selected from silicon oxide, silicon nitride, silicon oxynitride, silicon carbonitride, or metal oxides such as tantalum oxide, hafnium oxide, or aluminium oxide, and a composition thereof. A method for forming the gate insulating layer is selected from a physical vapor deposition (PVD) method, an atomic layer deposition (ALD) method, a pulsed laser deposition (PLD) method, chemical vapor deposition (CVD), vacuum evaporation, furnace tube deposition, and the like. Preferably, the method for forming the gate material is the atomic layer deposition (ALD) method.

In some embodiments, a bit line structure material is selected from a metal, a metal nitride, a metal oxide, a metal silicide, conductive carbon, doped or undoped polysilicon, doped or undoped single-crystal silicon, and a combination thereof, e.g., copper (Cu), aluminium (Al), tungsten (W), titanium (Ti), titanium nitride (TiN), titanium aluminium nitride (TiAlN), titanium carbonitride (TiCN), tantalum (Ta), tantalum nitride (TaN), tantalum aluminium nitride (TaAlN), tantalum carbonitride (TaCN), ruthenium (Ru), platinum (Pt), or a combination thereof. A method for forming the bit line structure material is selected from a physical vapor deposition (PVD) method, an atomic layer deposition (ALD) method, a pulsed laser deposition (PLD) method, chemical vapor deposition (CVD), vacuum evaporation, furnace tube deposition, and the like. Preferably, the method for forming the bit line structure material is the atomic layer deposition (ALD) method.

In some embodiments, the storage node is selected from a storage capacitor. A lower electrode of the storage capacitor is selected from a metal, a metal nitride, a metal oxide, a metal silicide, conductive carbon, doped or undoped polysilicon, doped or undoped single-crystal silicon, and a combination thereof, e.g., copper (Cu), aluminium (Al), tungsten (W), titanium (Ti), titanium nitride (TiN), titanium aluminium nitride (TiAlN), titanium carbonitride (TiCN), tantalum (Ta), tantalum nitride (TaN), tantalum aluminium nitride (TaAlN), tantalum carbonitride (TaCN), ruthenium (Ru), platinum (Pt), or a combination thereof. Preferably, the lower electrode is titanium nitride (TiN). A method for forming the lower electrode is selected from a physical vapor deposition (PVD) method, an atomic layer deposition (ALD) method, a pulsed laser deposition (PLD) method, chemical vapor deposition (CVD), vacuum evaporation, furnace tube deposition, and the like. Preferably, the method for forming the lower electrode is the atomic layer deposition (ALD) method.

In some embodiments, the storage node is selected from a storage capacitor. An upper electrode of the storage capacitor is selected from a metal, a metal nitride, a metal oxide, a metal silicide, conductive carbon, doped or undoped polysilicon, doped or undoped single-crystal silicon, and a combination thereof, e.g., copper (Cu), aluminium (Al), tungsten (W), titanium (Ti), titanium nitride (TiN), titanium aluminium nitride (TiAlN), titanium carbonitride (TiCN), tantalum (Ta), tantalum nitride (TaN), tantalum aluminium nitride (TaAlN), tantalum carbonitride (TaCN), ruthenium (Ru), platinum (Pt), or a combination thereof. Preferably, the upper electrode is laminated titanium nitride (TiN) and polysilicon. A method for forming the upper electrode is selected from a physical vapor deposition (PVD) method, an atomic layer deposition (ALD) method, a pulsed laser deposition (PLD) method, chemical vapor deposition (CVD), vacuum evaporation, furnace tube deposition, and the like.

In some embodiments, the common electrode structures are connected to multiple stacked array structures. Optionally, the stacked array structures are disposed at intervals along an extension direction of the common electrode structures. Optionally, multiple stacked array structures are formed on both sides of the common electrode structures.

It may be understood that, in the present disclosure, first lead-out wires and first pseudowires that are alternately disposed at relatively different layers may increase a distance between first lead-out wires at different layers, thereby reducing a parasitic capacitance.

In another aspect, because the distance between first lead-out wires at different layers becomes large, the first lead-out wire can be made wider, to reduce a resistance of the first lead-out wire, thereby reducing a loss of the semiconductor device.

In still another aspect, because the first lead-out wire, the second contact pad, and the second contact plug are unibody, or the first lead-out wire and the second contact pad are unibody, or the second contact pad and the second contact plug are unibody, a contact resistance can be reduced, so that a loss of the semiconductor device is reduced.

In yet another aspect, the first lead-out structure connected to the second lead-out structure close to the first lead-out structure is located at an upper layer than the first lead-out structure connected to the second lead-out structure far from the first lead-out structure, and the second contact pad of the second lead-out structure far from the first lead-out structure passes through a lower layer to be connected to the corresponding first lead-out structure. When more layers are disposed at between two intermediate contact pads, e.g., three layers or five layers, a parasitic capacitance between second contact pads that are at different layers and whose projections on the substrate in the first direction partially overlap may be reduced.

Various semiconductor devices shown in the specific implementations may be utilized in electronic devices with a storage function. The electronic device may be a terminal device, e.g., a mobile phone, a tablet computer, a smart wristband, or may be a personal computer (personal computer, PC), a server, or a workstation. The storage function in the electronic devices may be implemented by the following memory: a dynamic random access memory (DRAM), a ferroelectric random access memory (FRAM), a phase change memory (PCM), a magnetic random access memory (MRAM), or a resistive random access memory (RRAM).

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A semiconductor device, comprising:
a substrate;
common electrode structures, the common electrode structures being stacked on the substrate in a first direction, and the first direction intersecting the substrate;
stacked array structures, the stacked array structures comprising first electrode structures, and the first electrode structures being stacked on the substrate in the first direction and being electrically connected to the common electrode structures disposed at same layers with the first electrode structures;
first lead-out structures, the first lead-out structures being stacked in the first direction and being connected to the common electrode structures disposed at same layers with the first lead-out structures, the first lead-out structures comprising first lead-out wires and first pseudowires that are disposed opposite to each other, and the first lead-out wires and the first pseudowires in the different first lead-out structures being alternately disposed in the first direction; and
second lead-out structures, the second lead-out structures comprising second contact pads and second contact plugs, the second contact pads being disposed at same layers with the corresponding first lead-out wires and being electrically connected to the corresponding common electrode structures through the corresponding first lead-out wires, the second contact plugs being disposed on the second contact pads, and the second contact plugs being staggered from each other in the first direction.

2. The semiconductor device according to claim 1, wherein
the first lead-out structures extend in a third direction, the second lead-out structures are staggered in the third direction, and the third direction is parallel to the substrate.

3. The semiconductor device according to claim 1, wherein
the first lead-out structures extend in a third direction, the third direction is parallel to the substrate, the second lead-out structures are disposed in a second direction, projections of the second lead-out structures on the substrate in the first direction partially overlap, and the second direction is parallel to the substrate and intersects the third direction.

4. The semiconductor device according to claim 3, wherein
the first lead-out wires connected to the second lead-out structures whose projections on the substrate in the first direction partially overlap are spaced apart by at least one layer.

5. The semiconductor device according to claim 1, wherein
the first electrode structures comprise bit line structures or word line structures.

6. The semiconductor device according to claim 1, wherein
both ends of the first lead-out structures are connected to the common electrode structures.

7. The semiconductor device according to claim 1, wherein
the second contact pads and the first lead-out wires are unibody.

8. The semiconductor device according to claim 1, wherein
the second contact pads and the second contact plugs are unibody.

9. The semiconductor device according to claim 1, wherein
each of the first pseudowires comprises laminated polysilicon and silicon nitride.

10. The semiconductor device according to claim 4, wherein
the first electrode structures comprise bit line structures or word line structures.

11. The semiconductor device according to claim 4, wherein
both ends of the first lead-out structures are connected to the common electrode structures.

12. The semiconductor device according to claim 4, wherein
each of the first pseudowires comprises laminated polysilicon and silicon nitride.

13. A manufacturing method for a semiconductor device, comprising:
providing a substrate on which a stacked structure is formed;
forming common electrode structures in the stacked structure;
forming stacked array structures in the stacked structure, the stacked array structures comprising first electrode structures;
forming first lead-out structures in the stacked structure, the first lead-out structures comprising first lead-out wires and first pseudowires that are disposed opposite to each other, the first lead-out wires and the first pseudowires in the different first lead-out structures being alternately disposed in the first direction, and the first direction intersecting the substrate; and
forming second lead-out structures in the stacked structure, the second lead-out structures comprising second contact pads and second contact plugs;
the common electrode structures being electrically connected to the first electrode structures formed at same layers with the common electrode structures, the second lead-out structures being electrically connected to the common electrode structures through the first lead-out wires, the second contact plugs being formed on the second contact pads, and the second contact plugs being staggered from each other in the first direction.

14. The manufacturing method for a semiconductor device according to claim 13, wherein
the first lead-out wires, the second contact pads, and the second contact plugs are formed in a same step.

15. The manufacturing method for a semiconductor device according to claim 13, wherein
forming the first lead-out structures comprises:
first forming filling layers, the filling layers padding positions of the first lead-out structures;
forming trench structures corresponding to the second lead-out structures, and exposing the corresponding filling layers;
removing the exposed filling layers; and
forming the first lead-out wires, the second contact pads, and the second contact plugs, the remaining filling layers forming the first pseudowires.

16. The manufacturing method for a semiconductor device according to claim 15, wherein
the filling layers are formed by depositing polysilicon and silicon nitride in a lamination manner.

17. The manufacturing method for a semiconductor device according to claim 13, wherein
the forming the stacked structure comprises: alternately forming a silicon layer and a silicon-germanium layer.

18. The manufacturing method for a semiconductor device according to claim 13, wherein
the first electrode structures comprise bit line structures or word line structures.

19. The manufacturing method for a semiconductor device according to claim 13, wherein
both ends of the first lead-out structures are connected to the common electrode structures.

20. The manufacturing method for a semiconductor device according to claim 13, wherein
the first lead-out structures extend in a third direction, the third direction is parallel to the substrate, the second lead-out structures are formed in a second direction, projections of the second lead-out structures on the substrate in the first direction partially overlap, and the second direction is parallel to the substrate and intersects the third direction.
